(19) United States
(12) Patent Application Publication
(10) Pub. No.: US 2015/0376776 A1
(43) Pub. Date: Dec. 31, 2015

(54) VARIABLE-TEMPERATURE MATERIAL GROWTH STAGES AND THIN FILM GROWTH

(71) Applicant: Veeco Instruments, Inc., Plainview, NY (US)

(72) Inventors: Arindom Datta, Plainview, NY (US); Frank M. Cerio, Albany, NY (US); Sandeep Kohli, Plainview, NY (US); Boris L. Druz, Plainview, NY (US)

(21) Appl. No.: 14/768,027

(22) PCT Filed: Feb. 13, 2014
(86) PCT No.: PCT/US14/16204

§ 371 Date: Aug. 14, 2015

Related U.S. Application Data
(60) Provisional application No. 61/764,819, filed on Feb. 14, 2013.
(60) Provisional application No. 61/778,449, filed on Mar. 13, 2013.

(51) Int. Cl. C23C 14/54

(52) U.S. Cl. CPC C23C 14/541

(57) ABSTRACT

A thin film of material on a substrate is formed in a continuous process of a physical vapor deposition system, in which material is deposited during a variable temperature growth stage having a first phase conducted below a temperature of about 500° C., and material is continuously deposited as the temperature changes for the second phase to above about 800° C.

### FIELD OF THE INVENTION

The present invention generally relates to thin films and methods of forming them using physical vapor deposition techniques. More particularly, the present invention relates to forming thin films that can be used as buffer layers in semiconductor materials.

### BACKGROUND

Thin film deposition techniques are used to form thin films on underlying substrates. Several types of thin film deposition techniques exist, including physical vapor deposition, chemical vapor deposition, atomic layer deposition, and others. Electronic semiconductor devices are often manufactured using thin film deposition techniques. For example, light-emitting diodes (LEDs) typically include several layers of thin crystalline III-V semiconducting materials deposited onto a substrate. When an electric potential is applied across the LED, electrons can transition between the layers of materials, causing light to be emitted.

A common LED substrate material is sapphire, a crystalline material of aluminum oxide. Growth of a crystalline thin film of a first material on the surface of a second dissimilar material, known as hetero-epitaxy, can be difficult and usually requires intermediate layers of additional materials that join well with both the first and second materials. For example, nitride-based electronic and optoelectronic devices (such as gallium nitride LEDs) are typically grown hetero-epitaxially on sapphire substrates by high temperature metal organic chemical vapor deposition (MOCVD). However, there is a 16% lattice mismatch between sapphire and GaN, if the GaN is deposited directly on the sapphire substrate an accumulation of compressive strain at the sapphire/GaN interface leads to periodic GaN crystal dislocations, with resulting defect densities of well over 10¹¹/cm2. At such defect levels, device properties (e.g. optical emission efficiency) are very poor. Furthermore, defect density uniformity across a wafer impacts brightness uniformity, and therefore binning yield.

To ameliorate these challenges, manufacturers have developed nucleation and buffer pre-layers, typically low temperature MOCVD-GaN (LT-GaN)) consisting of a ˜0.5 um low-density GaN nucleation layer and a ˜2-3 μm undoped GaN buffer. Low temperature nucleation produces a defective surface which is then repaired through several time consuming process steps at variable temperatures and pressures. These “recovery” steps strongly dictate the number of defects that propagate into the remaining LED structure. The LT-GaN nucleation and buffer reduces the dislocation density in the subsequent n-GaN layer to about 109/cm², but requires up to three hours for growth and anneal and accounts for about 25% of the total epitaxial process cost. Such buffer layers have been used to reduce hetero-epitaxy induced defects by more than 100×, as reported by S. Y. Karpov and Y. N. Makarov, “Dislocation Effect on Light Emission Efficiency in Gallium Nitride”, Applied Physics Letters 81, 4721 (2002).

One known alternate for a LT-GaN buffer layer is an AlN buffer layer, commonly deposited by Chemical Vapor Deposition (CVD) methods. CVD growth can provide highly epitaxial films but is reportedly associated with surface roughness, which is detrimental to device performance. Furthermore defects densities in CVD films still limit device efficiency. Cuomo, U.S. Pat. No. 6,692,568, and Hanawa, US Patent Publication 2009/02897270 discuss fabricating high quality AlN buffer layers using Physical Vapor Deposition (PVD) methods, typically at elevated temperatures to induce epitaxial growth. Some advantages are that PVD tools have low cost of ownership, and PVD processes are relatively easy to control and do not require use or generation of hazardous gases. Furthermore, it has been found that defect densities of GaN grown on PVD-AlN buffer layers can be reduced by 2-3× compared to GaN grown on LT-GaN buffer layers.

However, one problem with PVD AlN deposited hetero epitaxially on sapphire and other substrates is high film stress. This stress can be compounded when elevated deposition temperatures are needed in order to achieve certain film properties. Higher films stress induces strain and bow on the substrate. This film strain and wafer bow negatively impacts the film properties and any subsequent processing this material may need to manufacture relevant devices. It is more difficult to control wafer temperature if they are excessively bowed. Polishing processes such as CMP or patterning by contact lithography during processing are impacted by wafer bow. Film delamination, cracking and increased defect density is observed when films are deposited on bowed or strained wafers. Backside metallization, bonding, and wafer thinning processes are not possible if wafer bow exceeds certain parameters. These problems are becoming more acute as commercial nitride device fabricators are scaling up from 100-150 mm to 200 mm or larger diameter substrates to reduce device costs.

PVD-AlN films deposited at low temperature have been in wide use for other applications more than a decade, most notably as an FBAR piezoelectric resonator material, and the volume of technical knowledge regarding its growth morphology is extensive, but not directed to buffer layer applications. The deposition of PVD-AlN films with tailored stress, grain size, column densities, and crystal orientation is explored in L. La Spina, et al, “Characterization of PVD Aluminum Nitride for Heat Spreading in RF IC's”, http://ectm.ewi.tudelft.nl/publications_pdf/document1124.pdf , and V. V. Felmetsger et al, “Innovative technique for tailoring intrinsic stress in reactively sputtered piezoelectric aluminum nitride films,” JVST A, Vol. 27, 417 (2009). However, such films are generally polycrystalline or amorphous and not suitable for use as buffer layers for nitride-based devices.

There is a need, therefore, for thin film layers and high productivity methods for preparing the same that address one or more of the drawbacks discussed above and are suitable for use as a buffer layer for nitride-based devices.

### SUMMARY OF THE INVENTION

Embodiments of the present invention are directed to a method of producing a thin film of material on a substrate in a continuous process of a physical vapor deposition system, in which material is deposited during a variable temperature growth stage having a first lower temperature phase conducted below a first temperature, and at the conclusion of the first phase, material is continuously deposited as the temperature increases for a second higher temperature phase performed above a second temperature, wherein the second temperature is at least 50° C. greater than the first temperature.

According to one embodiment of the invention, the first temperature is below about 600° C. and the second temperature is above about 800° C. In embodiments of the invention, the substrate is heated sequentially to a temperature below the first temperature and then to a temperature above the second temperature, while depositing material. Deposition of material may be continuous, or may be slowed or ceased during a time between the first phase and the second phase.

According to an embodiment of the invention, the first temperature may be substantially room temperature, and that phase may have a duration of less than 30 seconds to deposit material of a thickness of less than 90 angstroms. The second phase may have duration of greater than 100 seconds and deposit material of a thickness of less than about 600 angstroms.

A thin film formed according to the concepts of the present invention has been found to be a low stress buffer layer, enabling a low stress interface between the underlying substrate and additional film layers deposited onto the buffer layer.

Various additional features and advantages of the invention will become more apparent to those of ordinary skill in the art upon review of the following detailed description of the illustrative embodiments taken in conjunction with the accompanying drawings.

### BRIEF DESCRIPTION OF THE DRAWINGS

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 is schematic view depicting features of a physical vapor deposition sputtering system used to form a thin film on a substrate according to the concepts of the present invention.

FIG. 2 is a schematic view depicting the growth of a thin film layer on a substrate following a first phase of a material growth stage.

FIG. 3 is a schematic view depicting the growth of a thin film on a substrate following first and second phase of a material growth stage.

FIG. 4A is a graph of the measured film stress as a function of the thickness of the film grown in the first phase, and FIGS. 4B and 4C are graphs of x ray diffraction peak widths as a function of the thickness of the film grown in the first phase,

FIG. 5A is a TEM image of a PVD-generated AlN layer on Sapphire, created by prior art processes, showing a disrupted moiré pattern at the Sapphire-AlN interface, and FIG. 5B is a TEM image of a PVD-generated AlN layer on Sapphire created according to the present invention, showing a less disrupted moiré pattern at the Sapphire-AlN interface, and FIG. 5C is a TEM image of a PVD generated AlN layer on sapphire created with the first phase only.

### DETAILED DESCRIPTION OF THE ILLUSTRATIVE EMBODIMENTS

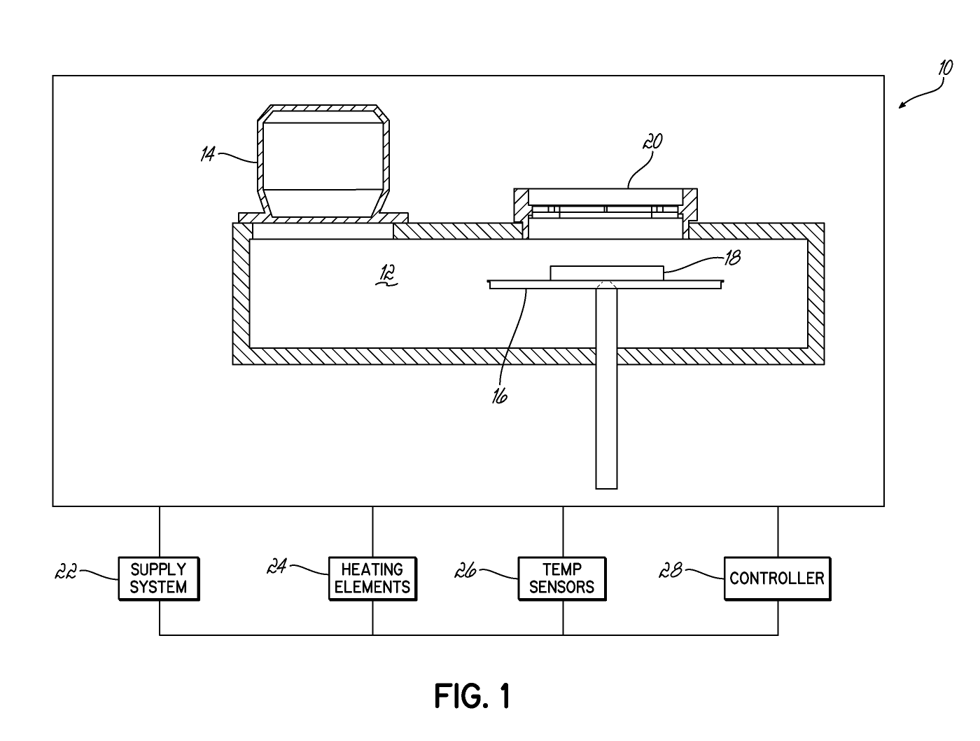

Referring first to FIG. 1, a physical vapor deposition (PVD) sputtering system is shown and is designated generally by the numeral 10. The PVD sputtering system 10 is used to produce thin films of material on a substrate according to the concepts of the present invention. It will be appreciated that the PVD sputtering system 10 is merely exemplary, however, and that the teachings contained herein can also be applied to other PVD systems.

PVD sputtering system 10 generally includes a deposition chamber 12. A vacuum pump 14 is provided to control the pressure (vacuum or otherwise) within the deposition chamber 12. A substrate carrier 16 is provided for supporting a substrate 18 in the deposition chamber 12. In the embodiment shown, the substrate carrier 16 is a rotating carrier that rotates the substrate 18 in the deposition chamber 12. The PVD sputtering system also includes a sputtering target 20, which provides a source of material that is sputtered off the sputtering target 20 and deposited onto the substrate 18. Deposition of material onto the substrate 18 is known generally as “growth”. In the embodiment shown, the sputtering target 20 is a magnetron envelope. A supply system 22 is also provided for delivering one or more gases to the deposition chamber 12. Heating elements 24 are also provided for adjusting the temperature of the substrate 18 in the deposition chamber 12. For example, the heating elements 24 may be resistive heaters contained in walls that define the deposition chamber 12, in the substrate carrier 16, or in any other suitable location. Temperature sensors 26 may also be provided for detecting various temperatures within the PVD sputtering system 10, such as the temperatures of the substrate 18, the substrate carrier 16, and within the deposition chamber 12. A controller 28 is provided for controlling all aspects of the PVD sputtering system, including the pressure in the deposition chamber 12, the temperatures of the various components of the PVD sputtering system 10, controlling the PVD sputtering system 10 so as to begin and stop the deposition of material onto the substrate 18, and other features related to producing a thin film. The PVD sputtering system 10 may be activated according to methods well known in the art, and is operated to produce a thin film on the substrate 18 according to the following concepts.

Particularly, the PVD sputtering system 10 is operated to produce a thin film of material on the substrate 18 during a variable-temperature material growth stage. During the variable-temperature material growth stage, the temperature of the substrate 18 is changed. Using heating elements 24 temperature can be changed, and the temperature of the substrate 18 is monitored using the temperature sensors 26. The controller 28 monitors the temperature sensors 26 and controls the heating elements 24 to the appropriate temperature of the substrate 18 and within the deposition chamber 12.

The variable-temperature material growth stage includes at least two phases of growth, in which some of the conditions in the deposition chamber 12 vary widely between those two phases.

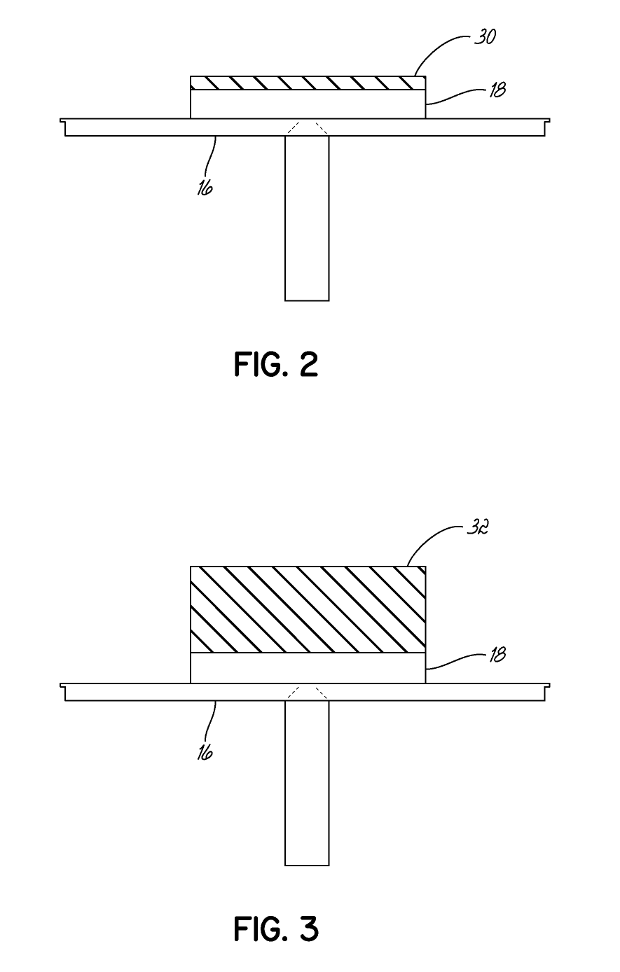

In a first phase, the PVD sputtering system 10 is operated below a first temperature, and material is deposited onto the substrate 18. In a second phase, the PVD sputtering system 10 is operated above a second temperature, and material continues to be deposited onto the substrate 18. Advantageously, the first phase precedes the second phase, so that material is continuously deposited onto the substrate during the first phase and then during the second phase, and the material deposited in the second phase is deposited on top of, and in addition to, the material deposited onto the substrate during the first phase. FIGS. 2 and 3 illustrate material 30 and 32 as it appears deposited onto the substrate 18 following the first and second phases, respectively.

More particularly, the first phase of the material growth stage is characterized by an operational temperature where the temperature of the substrate 18 is about 500° C. or lower, down to about room temperature. In this first phase, the PVD sputtering system 10 is operated so that material from the sputtering target 20 is deposited onto the substrate 18. The deposition time during this first phase, that is, the duration of time that material is deposited onto the substrate 18 while at this temperature, is about 30 seconds or less, and as short as 4 seconds. In various embodiments, the first phase time may be adjusted within a wide range, when used with different deposition rates and carrier rotation speeds. During this first phase, a thin film layer 30 of material begins to grow on the substrate 18 as seen in FIG. 2, which has a generally uniform thickness. Advantageously, the first phase is concluded by the increase in the temperature of the substrate 18, when the thickness of the thin film layer 30 is less than about 90 angstroms, but more than about 5 angstroms. Of course, the duration of the first phase may be adjusted to achieve a desired thickness.

The second phase of the material growth stage is characterized by a temperature of the substrate 18 being greater than in the first phase. In particular, the temperature of the substrate 18 during the second phase is elevated to about 800° C. or higher. In this second phase, the PVD sputtering system 10 is continuously operated so that material from the sputtering target 20 is deposited onto the substrate 18. More particularly, the material continues to be deposited onto the thin film layer 30 already formed on the substrate 18 during the first phase of the material growth stage, so that when the second phase is completed a thin film 32 of material is formed on the substrate 18 comprising the material deposited in the first phase and the material deposited in the second phase, as well as, potentially, material deposited during the temperature transition between the two phases.

Thus, after the first phase a thin film layer 30 is formed, and after the second phase a thin film 32 is completed. The deposition time during this second phase is typically about 100 seconds. Here again, second phase deposition time can be varied depending upon the deposition rate and desired buffer layer thickness, and can be less than 100 seconds and greater than 250 seconds. Advantageously, the second phase is concluded when the thickness of the thin film 32 is less than about 600 angstroms, but more than about 200 angstroms. Of course, the duration of the second phase may be adjusted to achieve a desired thickness.

The first and second phases of the material growth stage may be conducted in several different ways. For example, the PVD system 10 may be controlled so that an appropriate temperature of the substrate 18 (“substrate temperature”) is reached and maintained for the first phase (a temperature less than about 500° C.). Once that temperature is reached and maintained, the PVD system 10 may be operated so that material is deposited onto the substrate 18. Once appropriate time duration has passed or a desired thickness of the thin film layer 30 has been reached, the PVD system 10 is controlled so that further deposition of material on the substrate 18 slows or ceases. Then, the PVD system may be controlled so that an appropriate substrate temperature is reached and maintained for the second phase (a temperature greater than about 800° C.). Once that temperature is reached and maintained, the PVD system 10 may be operated so that material is deposited onto the substrate 18 (and onto the thin film layer 30 created during the first phase). Once appropriate time duration has passed or a desired thickness of the thin film 32 has been reached, the PVD system 10 is controlled so that further deposition of material on the substrate 18 ceases. Thus, in this example, the temperature during the first and second phases is maintained and deposition of material onto the substrate 18 is interrupted between the first and second phases.

Other options are also possible. As a further example, either or both of the first and second phases of the material growth stage can be conducted as the substrate temperature changes. For example, the first phase of the material growth stage can be conducted while the substrate temperature is being increased from an initial temperature (such as room temperature) to the upper cutoff temperature for the first phase (again, a temperature less than about 500° C.). Also, the second phase of the material growth stage can be conducted once the substrate temperature increases and crosses the lower cutoff temperature for the second phase (again, a temperature greater than about 800° C.). In these examples, the substrate temperature during the first and second phases is not necessarily maintained.

Also, the sputtering target 20 may be selected so that a desired material is deposited onto the substrate 18. For example, it may be desirable to grow a thin film of aluminum nitride (AlN) on a particular substrate, and so an appropriate sputtering target 20 may be selected. Also, the particular substrate 18 may be chosen, and might be, for example, sapphire or silicon.

Other operational parameters of the PVD sputtering system 10 may also be controlled. For example, the gases provided by the supply system 22 may be chosen according to a particular application. Argon and nitrogen gas are commonly used in PVD systems, and the present invention may be used with those gases. The selection of the ratio of flows of those gases is within the skill of an ordinary practitioner, and may be chosen so that a constant ratio is maintained during both the first and second phases of the material growth stage. In addition, the pressure within the deposition chamber 12 may be chosen, and the selection of which is also within the skill of an ordinary practitioner. For example, a pressure of about 2 mT may be maintained during both the first and second phases of the material growth stage. Also, the electrical characteristics of the power supplied to the sputtering target 20 can also be controlled. For example, 2 kW may be applied at a frequency of 150 kHz can be applied to the sputtering target 20, such as to create 1.5 micro-second pulses, and these electrical characteristics may be maintained during both the first and second phases of the material growth stage. Of course, the selection and adjustment of these operational parameters may be made based on a particular application.

Thin films formed according to the concepts of the present invention may advantageously be used as buffer layers between the underlying substrate and additional film layers deposited onto the buffer layers.

Without intending to be constrained to any particular theory, it is believed that the thin film layer 30 deposited onto the substrate 18 during the first phase of the material growth stage is in amorphous form, which better adheres to the underlying substrate 18 in a low stress state. It is also believed that when additional material is deposited at a higher temperature during the second phase, the resulting thin film 32 is in epitaxial form, and provides desirable qualities as a buffer layer.

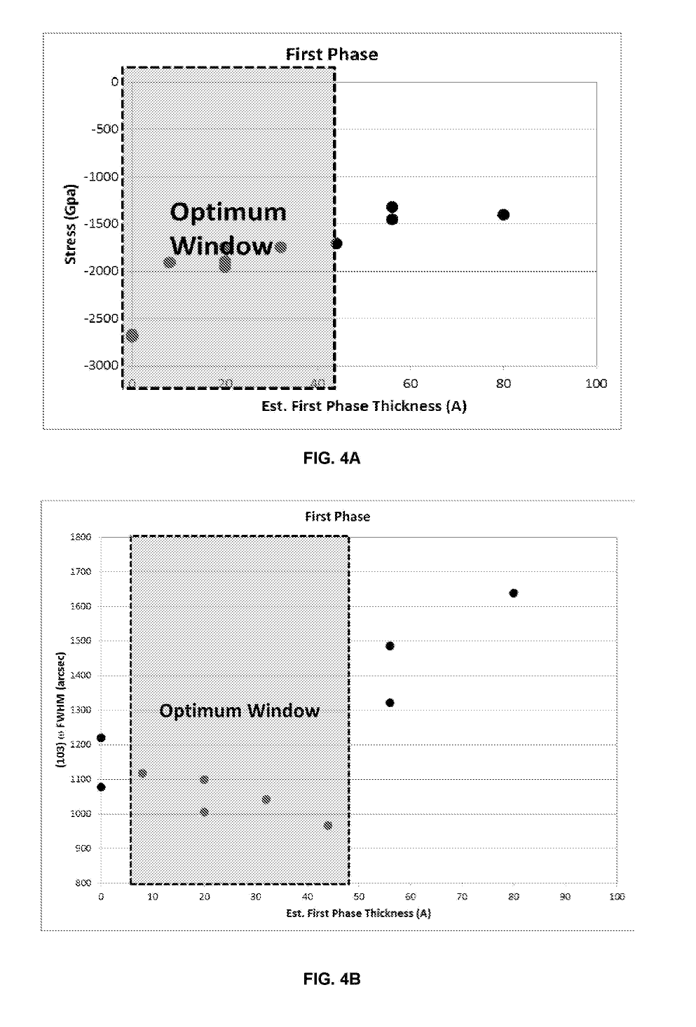

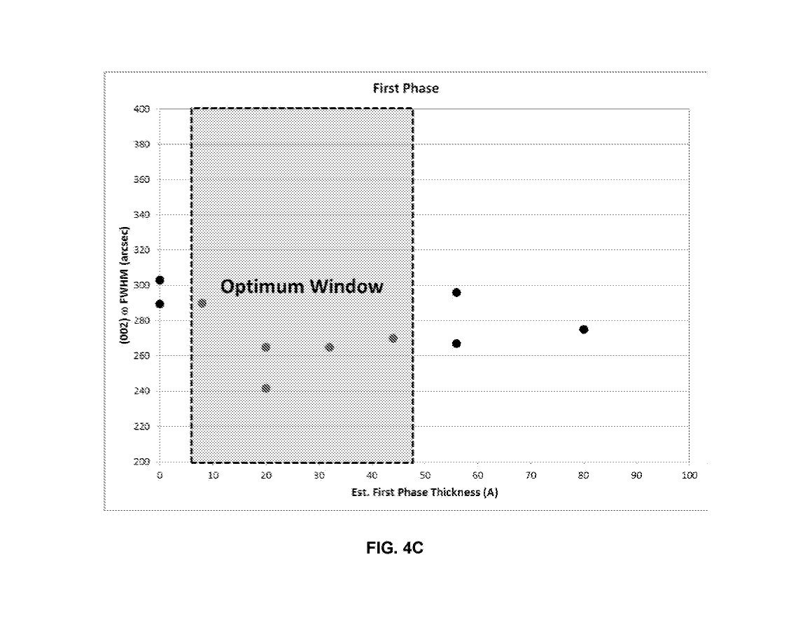

FIG. 4A is a graph of measured film stress of a wafer as a function of the thickness of the film grown in the first phase of a process such as described herein. The measurements shown on this graph were generated with a laser metrology tool used to measure wafer bow before and after deposition by the process described herein. A stress-strain formula for sapphire was used to calculate the stress values in GPa. Note that the zero value of stress is at the top of the graph, and thus the stress is reduced with the rising slope of the illustrated curve. As the thickness of the first phase deposition increases from 0 to approximately 40 Angstroms, stress is reduced, but the rate of stress reduction becomes near zero as the thickness approaches and exceeds approximately 60 Angstroms, indicating that first phase film growth is likely to have greatest advantage at thicknesses less than about 90 Angstroms. More specifically, growth in the first phase of less than 50 Angstroms is presently considered the optimum window for stress reduction, as illustrated in the graph.

FIGS. 4B and 4C illustrate X ray diffraction data from the film created by the process described herein, as a function of the first phase thickness. FWHM (in arcsec) measures defectivity of a crystalline film based upon the width of diffraction peaks. In the graph of FIG. 4B, the 103 peak width is charted and is in a range of 850-1650 FWHM (arcsec), for a range of first phase thickness from 0-90 Angstroms. In FIG. 4C, the 002 peak width is charted against the left axis and is in a range of 200-400 FWHM (arcsec). These measures are “full width half maximum”, and have a higher value where the diffraction peak for a particular crystalline feature is wider and less sharp, indicating more crystalline defects, and lower values where the particular crystalline feature is narrow and sharply defined, indicating fewer crystalline defects. Typically, low values of the 103 peak, indicating a sharp narrow peak, is indicative of a six fold symmetry of AlN crystalline growth, and therefore is indicative of epitaxial film growth. As seen, the 103 peak/edge defect rate reaches a minimal value at about 30-40 Angstroms and increases sharply above about 40 Angstroms of first phase thickness, whereas the 002 peak/screw defect rate decreases through the range up to about 40 Angstroms of first phase thickness. These two measures indicate that optimally low defect rates are potentially achieved with first phase thicknesses of about 50 Angstroms, which is in the middle of the ranges discussed above. The Optimum Window for first phase growth thickness has accordingly been noted on the graph.

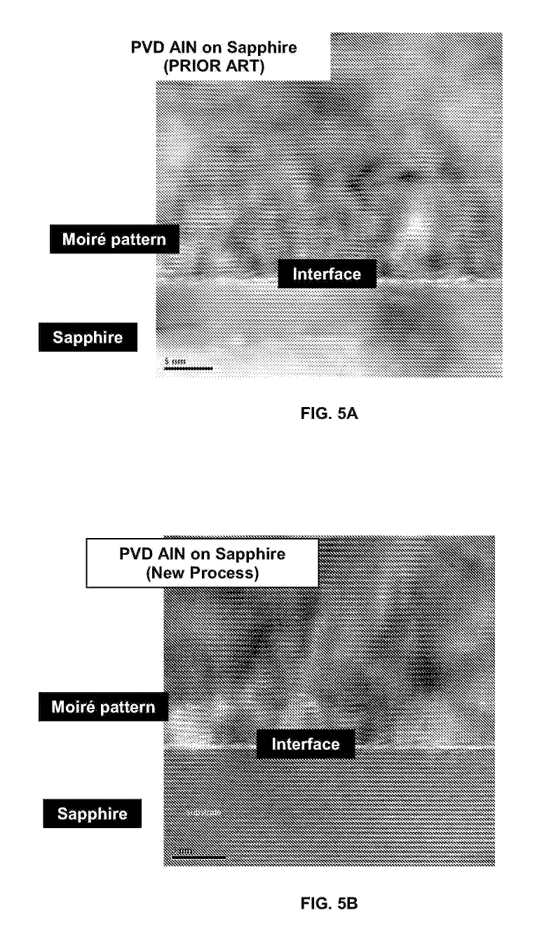

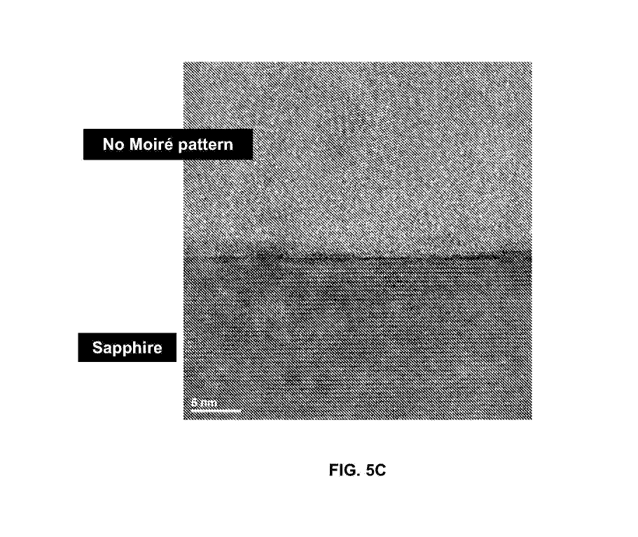

There is further evidence of the quality of the films produced by the multi-phase process of the present invention. FIG. 5A is a TEM image of a PVD-generated AlN layer on Sapphire, created by prior art processes, showing a disrupted moiré pattern at the Sapphire-AlN interface which is the result of defects in the AlN lattice, particularly visible near the AlN-Sapphire interface. FIG. 5B is a TEM image of a PVD-generated AlN layer on Sapphire created according to a multi-phase growth process of the present invention, showing a less disrupted moiré pattern at the Sapphire-AlN interface. For comparison, FIG. 5C is a TEM image of a PVD generated AlN layer on sapphire created with the First Phase only. No epitaxial growth of the AlN is observed under this condition.

While the present invention has been illustrated by the description of specific embodiments thereof, and while the embodiments have been described in considerable detail, it is not intended to restrict or in any way limit the scope of the appended claims to such detail. The various features discussed herein may be used alone or in any combination. Additional advantages and modifications will readily appear to those skilled in the art. The invention in its broader aspects is therefore not limited to the specific details, representative apparatus and methods and illustrative examples shown and described. Accordingly, departures may be made from such details without departing from the scope or spirit of the general inventive concept.

What is claimed is:

1. A method of producing a thin film of material on a substrate, comprising:
operating a physical vapor deposition system to deposit the material onto the substrate during a variable-temperature material growth stage,
wherein the variable-temperature material growth stage includes deposition of material during at least a first phase conducted below a first temperature, and a second phase conducted above a second temperature which exceeds the first temperature by at least 50° C.

2. The method of claim 1, wherein the first temperature is about 500° C. and the second temperature is about 800° C.

3. The method of claim 1, where the second temperature is above 900° C.

4. The method of claim 1, wherein operating a physical vapor deposition system includes continually depositing the material onto the substrate during an increase of temperature of at least 50° C. between the first and second phases.

5. The method of claim 1, wherein operating a physical vapor deposition system includes continually depositing the material onto the substrate during the first phase and during the second phase.

6. The method of claim 4, wherein depositing the material is slowed or ceased during a time between the first phase and the second phase.

7. The method of claim 1, wherein the first temperature is substantially room temperature.

8. The method of claim 1, wherein the first phase has a duration of less than 30 seconds.

9. The method of claim 1, wherein the second phase has a duration of greater than 100 seconds.

10. The method of claim 1, wherein at the time the second phase is initiated, the material has a thickness of less than about 90 angstroms.

11. The method of claim 2, wherein after the second phase, the material has a thickness of less than about 600 angstroms.

12. The method of claim 2, wherein after the second phase, the material has a thickness of less than about 1000 angstroms
